(19) United States
(12) Patent Application Publication
(10) Pub. No.: US 2006/0104034 A1
(43) Pub. Date: May 18, 2006

(54) Heat-dissipating device

(75) Inventors: Kuo-ying Tsai, Hsin Tien City (TW); Shih-Chang Ku, Hsin Tien City (TW)

Correspondence Address: BIRCH STEWART KOLASCH & BIRCH, PO BOX 747, FALLS CHURCH, VA, 22040-0747, US

(73) Assignee: VIA TECHNOLOGIES, INC.

(21) Appl. No.: 11/086,302

(22) Filed: Mar. 23, 2005

(30) Foreign Application Priority Data
Nov. 12, 2004 (TW) 93134845

(51) Int. Cl. H05K 7/20

(52) U.S. Cl. 361/704

(57) ABSTRACT

A heat-dissipating device has multiple conduction paths, and is especially adapted to a package with MPMs (Multiple Packaging Modules). The package is mounted on one side of a PCB. The heat-dissipating device has a first heat-dissipating unit, a second heat-dissipating unit, and a thermal bridge unit. The first heat-dissipating unit is contacted with a first heat source of the package element. The second heat-dissipating unit penetrates through the PCB and contacts with a second heat source of the package element. The thermal bridge unit penetrates through the PCB and connects the first heat-dissipating unit and the second heat-dissipating unit.

### BACKGROUND OF THE INVENTION

1. Field of the Invention

The present invention relates to a heat-dissipating device, and particularly to a heat-dissipating device being adapted for a package with MPMs (Multiple Packaging Modules) and providing multiple dissipating paths to enhance heat-dissipating efficiency.

2. Description of the Related Art

As new and different electronic products are being developed quickly, semiconductor chips that are used for processing commands in electronic products are becoming more and more complex, and often multiple chips are packaged in a package. Therefore, the thermal requirements of heat-dissipation of the package are more and more important. Some package comprises a single chip mounted on a top surface thereof and a heat-dissipating device mounted on a bottom surface thereof for heat-dissipating. Some package is respectively mounted at least one chip on the top surface and at least another chip on the bottom surface. Providing a good heat-dissipating structure for such a compact package is a very important factor of the performance of electronic equipment.

Please refer to FIG. 1, which is an assembled cross-sectional view of a conventional heat-dissipating structure. A heat-dissipating structure 8 of the prior art elementarily comprises a heat sink 84 which applied on a package 82 for heat dissipating, especially on a multiple packaging modules (MPM). However the package 82 has two stacked heat sources, an upper chip 825 as a first heat source and a lower chip 828 as a second heat source. The upper chip 825 is mounted on a top surface of an upper substrate 824, and the lower chip 828 is mounted on a bottom surface of a lower substrate 822. The heat sink 84, which is usually assembled on a PCB 9 via a plurality of screw bolts 86, only contacts a heat spreader 826. The heat spreader 826 is a sheet-like thermal conductor disposed on the upper surface of the package 82 for heat-dissipating. In the prior art, the heat dissipating path of the second heat source (lower chip) 828 must pass through the upper chip 825 and then transfer to the heat spreader 826. The heat dissipating path has a poor heat dissipating capability in an integral view of the package 82 and raises the operating temperature of the package 82.

With a view of enhancing heat-dissipating capacity, the prior art usually adds a fan 88 on the heat sink 84 for dissipating heat actively. However, the fan 88 has a reliability problem because of its limited operating lifespan. Especially in a host system that does not allow any failure occurred, the lifespan of the fan seriously reduced the reliability of the host system. Moreover, the fan will produce noise and upset the user of the machine. Furthermore, the fan increases the overall cost of the machine.

The height of the above-mentioned heat-dissipating device is also limited by the space of the housing. The heat must pass through air in the housing by convection and then transfers to the housing. Because air is not a good thermal conductor and heat is easily trapped in the housing, so that such conventional heat-dissipating devices cannot provide a good heat-transfer path to dissipate the heat to the housing.

Therefore, the heat-dissipating device of the prior art still has some inconveniences and disadvantages that need to be improved upon.

### SUMMARY OF THE INVENTION

An objective of the present invention is to provide a heat-dissipating device with multiple dissipating paths to enhance heat-dissipating efficiency, especially adapted to a package with MPMs (Multiple Packaging Modules).

Another objective of the present invention is to provide a heat-dissipating device that efficiently dissipates heat without any active elements, such as a fan. Therefore it increases the reliability of electronic products and prolonging their lifespan.

In order to achieve the above objectives, the present invention provides a heat-dissipating device comprising of a first heat-dissipating unit, a second heat-dissipating unit, and at least one thermal bridge unit. The first heat-dissipating unit contacts with a first heat source of a package and is positioned on one side of a PCB where the package is disposed on. The second heat-dissipating unit which is positioned on another side of the PCB penetrates through the PCB and contacts a second heat source of the package. The thermal bridge unit penetrates through the PCB and connects with the first heat-dissipating unit and the second heat-dissipating unit.

### BRIEF DESCRIPTION OF THE DRAWINGS

The invention will be better understood and objectives other than those set forth above will become apparent when consideration is given to the following detailed description thereof. Such description makes reference to the annexed drawings, wherein:

FIG. 1 is an assembled cross-sectional view of a conventional heat-dissipating structure;

FIG. 2 is an explored cross-sectional view of a heat-dissipating device according to the present invention;

FIG. 3 is an assembled cross-sectional view of the heat-dissipating device according to the present invention;

FIG. 4 is a side view of the heat-dissipating device assembled on a housing according to the present invention;

FIG. 5 is an explored cross-sectional view of the heat-dissipating device of another embodiment according to the present invention; and

FIG. 6 is an assembled cross-sectional view of the heat-dissipating device of third embodiment according to the present invention.

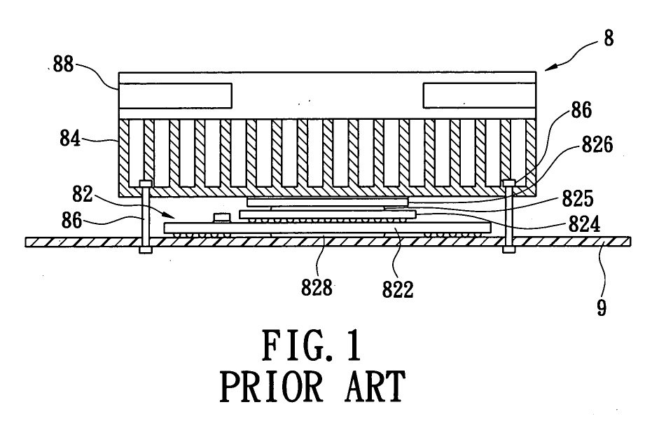

### DESCRIPTION OF THE PREFERRED EMBODIMENT

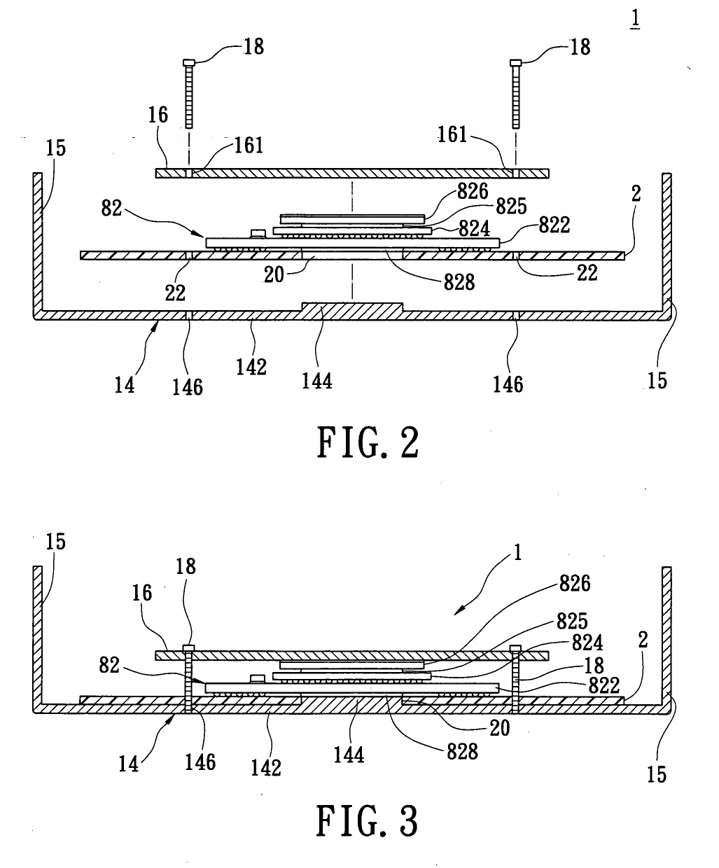

Please refer to FIG. 2 illustrated an explored cross-sectional view of a heat-dissipating device according to the present invention and FIG. 3 illustrated an assembled cross-sectional view thereof. The present invention provides a heat-dissipating device 1 for a package, especially for a MPM package 82 disposed on a PCB 2.

The package 82 illustrated in this embodiment is disposed at one side of the PCB 2 for processing commands of electronic equipment. The MPM package 82 comprises an upper substrate 824 and an upper chip 825 that is mounted on the upper substrate 824. A heat spreader 826 is mounted on a top surface of the upper chip 825, and the upper chip 825 is regarded as a first heat source. The MPM package 82 further comprises a lower substrate 822 and a second heat source 828 that is mounted on a bottom surface of the lower substrate 822. In this embodiment, the second heat source 828 is another chip. Besides, another heat spreader may mount on the second heat source 828 if the spacing between the second heat source 828 and the PCB 2 is allowed. The above-mentioned package 82 is just one illustrated embodiment according to the present invention, and the applied objective of the present invention is not limited to this kind of package. The present invention can be applied to a package having multiple heat sources. Thus, a package having one more chip is suitable to be the applied objective of the present invention.

One characteristic of the present invention is disposing a heat-dissipating unit 14 on another side of the PCB 2 opposite the side where the package 82 is disposed on. The heat-dissipating unit 14 penetrates through the PCB 2 to contact the second heat source 828 on the bottom of the package 82. The heat-dissipating unit 14 comprises a main part 142 which is not smaller than the PCB 2. Furthermore, the main part 142 is adjacent to the PCB 2 in this embodiment, as shown in FIG. 3. Therefore, even the main part 142 can act as a rigid support of the PCB 2 to avoid the PCB 2 becoming warped.

In this embodiment, for contacting the bottom of the package 82, at least one through hole 20 is formed on the PCB 2 to expose the second heat source 828 on the bottom of the package 82. Therefore, it provides the package 82 with another heat dissipating path for transferring the heat of the second heat source 828 outside without passing through the upper chip 825. The heat-dissipating unit 14 is opposite the package 82 and comprises a connecting part 144 that passes through the through holes 20 to touch the second heat source 828. The main part 142 of the heat-dissipating unit 14 is like a sheet to have a great heat-dissipating area, which can disperse the heat conducted from the connecting part 144. The present invention therefore provides an innovative and good heat-dissipating path for the second heat source 828.

In the practice, the present invention comprises the above-mentioned structure. In other words, the present invention only has the heat-dissipating unit 14, which could cooperate with any available heat-dissipating device provided in the prior art. Therefore, the present invention shortens the heat dissipating path of the package 82, and provides the second heat source 828 with a heat-dissipating shortcut to enhance heat-dissipating efficiency. In other words, the heat-dissipating unit 14 of the present invention can be treated as a second heat-dissipating unit comparing with the prior art.

Please refer to FIGS. 2 and 3. The present invention can be designed having a first heat-dissipating unit 16 and a second heat-dissipating unit 14. The first heat-dissipating unit 16 can conduct the heat from the first heat source (upper chip) 825 and dissipate it outside by contacting the heat spreader 826 of the package 82. In this embodiment, the first heat-dissipating unit 16 is connected with the second heat-dissipating unit 14 via a plurality of thermal bridge units 18. The thermal bridge units 18 can dissipate some heat to the second heat-dissipating unit 14. The PCB 2 and the second heat-dissipating unit 14 are formed with a plurality of connecting holes 22 and 146, respectively. The thermal bridge units 18 pass through the connecting holes 22 and 146 to connect with the second heat-dissipating unit 14. The thermal bridge units 18 could be screw bolts or posts that are formed integrally on the second heat-dissipating unit 14. The connecting holes 146 are not necessary if the thermal bridge units 18 are posts formed integrally on the second heat-dissipating unit 14. The second heat-dissipating unit 14 can further have at least one auxiliary heat-dissipating device 15 that is connected with one side of the second heat-dissipating unit 14. The auxiliary heat-dissipating device 15 could be a heat sink for assisting in heat-dissipation.

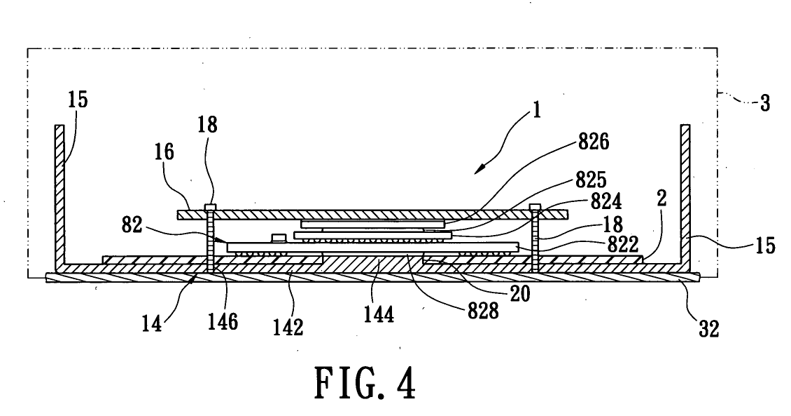

Please refer to FIG. 4, which is a side view of the heat-dissipating device assembled on a housing according to the present invention. Not only providing the first heat-dissipating unit 16 and the second heat-dissipating unit 14 with heat-dissipating paths, the heat-dissipating device 1 of the present invention can further contact a housing 3 surrounded peripherally for enhancing heat-dissipating capability. The second heat-dissipating unit 14 can contact a shell 32 of the housing 3 to directly conduct heat thereto. In the other words, that is what conventional heat-dissipating devices cannot achieve to transfer heat to the housing without the air convection. Therefore, the present invention solves the problem of a heat-dissipating path of the prior art, which transfers heat to the housing through the air convection. The present invention can even omit the shell 32. For example, the second heat-dissipating unit 14 is instead of the shell 32, and the auxiliary heat-dissipating device 15 can be treated as side shells.

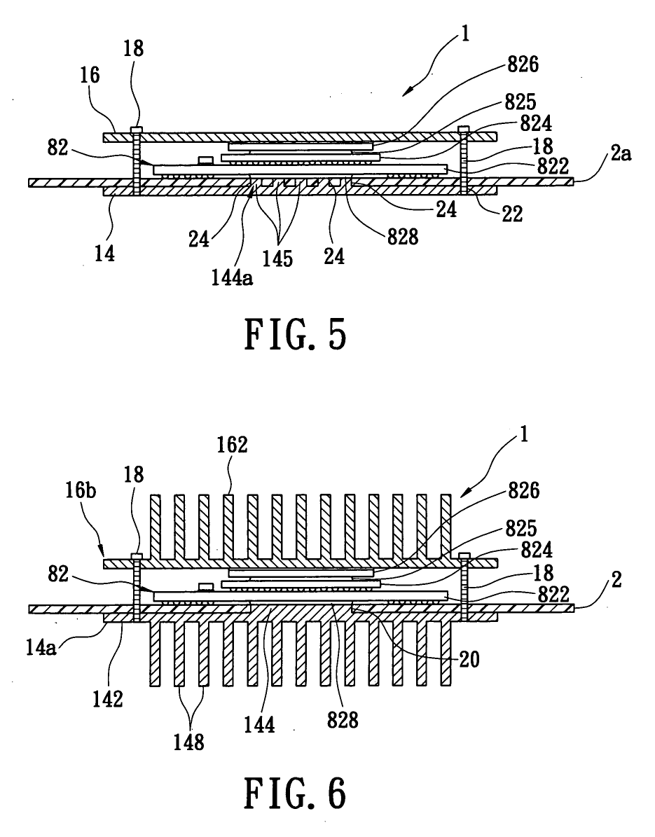

According to the characteristics as mentioned above, the first heat-dissipating unit 16 and the second heat-dissipating unit 14 could be various types. For example, the second heat-dissipating unit 14 can be a heat pipe, which has cycled fluid filled in the pipe and can transfer heat well and quickly to a far end by the phase changes of the fluid. The heat pipe is especially suitable for electronic equipment of limited height, such as a heat-dissipating device in a portable computer (or called notebook computer). The second heat-dissipating unit 14 can also be a metal block, or a heat sink formed with a plurality of fins (as shown in FIG. 6). The heat sink can be applied in electronic equipment without height limits, and has more heat-dissipating area for providing better heat-dissipating capability. In the same way, the first heat-dissipating unit 16 can be a heat pipe or a heat sink (as shown in FIG. 6).

Please refer to FIG. 5, which is an explored cross-sectional view of the heat-dissipating device of another embodiment according to the present invention. For avoiding the breaking of the circuits formed on the PCB, the PCB 2 can be formed with a plurality of through holes 24. Furthermore, the second heat-dissipating unit 14 has a connecting part 144a that is formed with a plurality of posts 145 extending into the through holes 24 respectively. The connecting part of the present invention can be formed integrally with the second heat-dissipating unit 14. For the easier manufacture, the connecting part can also be combined with the second heat-dissipating unit 14 by insertion.

Please refer to FIG. 6, which is an assembled cross-sectional view of the heat-dissipating device of third embodiment according to the present invention. The third embodiment provides a second heat-dissipating unit 14a and a first heat-dissipating unit 16b. The second heat-dissipating unit 14a is formed with a plurality of fins 148. The fins 148 are extended outwardly from the main part 142. In the third embodiment, the first heat-dissipating unit 16b is a heat sink, which is formed with a plurality of fins 162.

Therefore, the heat-dissipating device according to the present invention has the following characteristics and advantages:

1. The heat-dissipating device of the present invention provides multiple heat-dissipating paths to enhance its heat-dissipating capability. Therefore, the requirements in the heat-dissipating capability of the elements in the heat-dissipating paths are reduced, and the heat-conductive resistance between the package and the housing is lowered because of the increases in heat-dissipating paths.

2. The heat-dissipating device of the present invention effectively utilizes the space at the backside of the PCB to enhance heat-dissipating efficiency. The second heat-dissipating unit 14 can be treated as a rigid planar support for attaching onto the PCB 2, thereby avoiding warping of the PCB 2.

3. The heat-dissipating device of the present invention is especially adapted to the package with multiple packaging modules, and provides the stacked heat sources (chips) with an efficient heat dissipating capability. The present invention does not even need any active heat-dissipating units, such as a fan, therefore raising the reliability of electronic equipment and prolonging its lifespan.

4. The heat-dissipating capability of the present invention is not limited by the housing space and the elements on the PCB. The present invention further provides the housing as an immediate heat-dissipating element, which solves the problem of the heat-dissipating path through the air convection.

Although the present invention has been described with reference to the preferred embodiments thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A heat-dissipating device, applied to a package for dissipating heat, and said package assembled on one side of a PCB, comprising:
a heat-dissipating unit mounted on another side of said PCB opposite to said package element, wherein said heat-dissipating unit penetrates through said PCB and contacts a heat source at a bottom of said package element.

2. The heat-dissipating device as claimed in claim 1, wherein said package has at least one chip.

3. The heat-dissipating device as claimed in claim 1, wherein said package is a package of MPMs (multiple packaging modules) type.

4. The heat-dissipating device as claimed in claim 1, wherein said package comprises a substrate and a plurality of chips, wherein one of said chips is mounted on a top surface of said substrate, and one of another said chips is mounted on a bottom surface of said substrate.

5. The heat-dissipating device as claimed in claim 1, wherein said PCB is formed with at least one through hole corresponding to said heat source at said bottom of said package element, and said heat-dissipating unit has a connecting part passing through said through hole.

6. The heat-dissipating device as claimed in claim 5, wherein said PCB is formed with a plurality of through holes, and wherein said connecting part of said heat-dissipating unit has a plurality of posts respectively extending in said through holes.

7. The heat-dissipating device as claimed in claim 1, wherein at least one auxiliary heat-dissipating device is connected with a side of said heat-dissipating unit.

8. The heat-dissipating device as claimed in claim 1, wherein said heat-dissipating unit contacts with a housing.

9. The heat-dissipating device as claimed in claim 1, wherein said heat-dissipating unit is a second heat-dissipating unit, and further has a first heat-dissipating unit contacted with a heat source at a top part of said package element.

10. The heat-dissipating device as claimed in claim 9, further comprising at least one thermal bridge unit connecting said first heat-dissipating unit with said second heat-dissipating unit, wherein said PCB is formed with at least one connecting hole, and said thermal bridge unit passes through said connecting holes respectively.

11. A heat-dissipating device, comprising:
a first heat-dissipating unit, contacting with a first heat source of a package element, and positioned at an identical side of a PCB with said package element;
a second heat-dissipating unit, penetrating said PCB and contacting with a second heat source of said package element, and positioned at another side of said PCB; and
at least one thermal bridge unit, penetrating said PCB and connecting said first heat-dissipating unit with said second heat-dissipating unit.

12. The heat-dissipating device as claimed in claim 11, wherein said package has at least one chip.

13. The heat-dissipating device as claimed in claim 11, wherein said package is a package of MPMs (multiple packaging modules) type.

14. The heat-dissipating device as claimed in claim 11, wherein said package comprises a substrate and a plurality of chips, wherein one of said chips is mounted on a top surface of said substrate, and one of another said chips is mounted on a bottom surface of said substrate.

15. The heat-dissipating device as claimed in claim 11, wherein at least one of said first heat-dissipating unit or said second heat-dissipating unit extends with a plurality of fins.

16. The heat-dissipating device as claimed in claim 11, wherein said PCB is formed with at least one through hole corresponding to said bottom heat source of said package element, and wherein said heat-dissipating unit has a connecting part passing said through hole.

17. The heat-dissipating device as claimed in claim 16, wherein said PCB is formed with a plurality of through holes, and wherein said connecting part of said heat-dissipating unit has a plurality of posts extending into said through holes respectively.

18. The heat-dissipating device as claimed in claim 11, wherein at least one auxiliary heat-dissipating device is connected with a side of said second heat-dissipating unit.

19. The heat-dissipating device as claimed in claim 11, wherein said second heat-dissipating unit contacts with a housing.

20. The heat-dissipating device as claimed in claim 11, wherein said PCB is formed with at least one connecting hole, and wherein said thermal bridge unit passes through said connecting holes respectively.
